(19) United States
(12) Patent Application Publication
(10) Pub. No.: US 2023/0085878 A1
(43) Pub. Date: Mar. 23, 2023

(54) HIGH-VOLTAGE ISOLATION SEMICONDUCTOR DEVICE AND METHOD OF MAKING THE SAME

(71) Applicant: Shanghai Huahong Grace Semiconductor Manufacturing Corporation, Shanghai (CN)

(72) Inventor: Ziquan FANG, Shanghai (CN)

(73) Assignee: Shanghai Huahong Grace Semiconductor Manufacturing Corporation, Shanghai (CN)

(21) Appl. No.: 17/884,898

(22) Filed: Aug. 10, 2022

(30) Foreign Application Priority Data
Sep. 17, 2021 (CN) 202111092769.7

(51) Int. Cl. H01L 29/06; H01L 21/265

(52) U.S. Cl. CPC H01L 29/0623; H01L 21/265

(57) ABSTRACT

A high-voltage isolation semiconductor device and a method for manufacturing the same. The method includes providing a first conductivity type substrate of a substrate layer; performing first conductivity type ion implantation by means of first implantation energy to form a first conductivity type buried layer part A; performing first conductivity type ion implantation by means of second implantation energy to form a first conductivity type buried layer part B primary structure, wherein the first implantation energy is greater than the second implantation energy; growing a second conductivity type epitaxial layer on the first conductivity type substrate, wherein the first conductivity type buried layer part B primary structure extends into the second conductivity type epitaxial layer to form a first conductivity type buried layer part B; and forming a first conductivity type well region by means of first conductivity type ion implantation.

### CROSS-REFERENCE TO RELATED APPLICATION

This application claims priority to Chinese patent application No. CN 202111092769.7, filed at CNIPA on Sep. 17, 2021, and entitled “HIGH-VOLTAGE ISOLATION SEMICONDUCTOR DEVICE WITH IMPROVED NBTI AND A METHOD OF MAKING THE SAME”, the disclosure of which is incorporated herein by reference in entirety.

### TECHNICAL FIELD

The present application relates to the technical field of semiconductor integrated circuit manufacturing, in particular to a high-voltage isolation semiconductor device and method of making the same.

### BACKGROUND

In a half-bridge drive circuit, a high-voltage device and a low-voltage device need to be integrated in the same chip, and a level shift (LS) is designed between the high-voltage device and the low-voltage device to switch an input signal from one voltage domain to another voltage domain, thereby achieving communication between devices in different voltage domains.

Generally, the drain of the level shift is close to the high-voltage device, the drain of the level shift and the high-voltage device are both high voltages, and the drain of the level shift and the high-voltage device which are both high voltages are isolated from each other by a high-voltage isolation ring with a withstand voltage of greater than 600 volts. In the related art, by reducing the width of the high-voltage isolation ring and reducing the concentration of the high-voltage isolation ring, the high voltage withstand performance of the high-voltage isolation ring is achieved.

However, under some conditions where the working voltage VB of the high-voltage device is 10 volts to 30 volts greater than the drain voltage VD of the level shift, if the width of the high-voltage isolation ring is excessively small or the concentration is excessively low, the high-voltage isolation ring may be fully depleted quickly, and since the concentration of the substrate is very light, a depletion layer may expand downwards to a relatively large distance, resulting in the problem of punch-through that leads to a large electric leakage which is caused by no effective isolation between high-voltage circuits.

### SUMMARY

The present application provides a high-voltage isolation semiconductor device and a method for manufacturing the same, so as solve the problem of punch-through that leads to a large electric leakage which is caused by no effective isolation between high-voltage circuits in the related art.

In order to solve the above technical problem described in the background, a first aspect of the present application provides a method for manufacturing a high-voltage isolation semiconductor device, the method for manufacturing a high-voltage isolation semiconductor device including the following steps:

providing a first conductivity type substrate of a substrate layer, the substrate layer including at least a high-voltage device region, a level shift region, and an isolation region, the isolation region being isolated between the high-voltage device region and the level shift region;

in the first conductivity type substrate of the isolation region, performing first conductivity type ion implantation by means of first implantation energy to form a first conductivity type buried layer part A;

in the first conductivity type substrate on the first conductivity type buried layer part A, performing first conductivity type ion implantation by means of second implantation energy to form a first conductivity type buried layer part B primary structure, so that the first conductivity type buried layer part B primary structure extends downwards to contact the first conductivity type buried layer part A, wherein the first implantation energy is greater than the second implantation energy;

in the first conductivity type substrate on one side of the first conductivity type buried layer part A, forming a second conductivity type buried layer primary structure by means of second conductivity type ion implantation;

growing a second conductivity type epitaxial layer on the first conductivity type substrate, wherein a thermal process during the growth of the second conductivity type epitaxial layer enables the first conductivity type buried layer part B primary structure to extend into the second conductivity type epitaxial layer to form a first conductivity type buried layer part B and enables the second conductivity type buried layer primary structure to extend into the second conductivity type epitaxial layer to form a second conductivity type buried layer;

in the first conductivity type epitaxial layer on the first conductivity type buried layer part B, forming a first conductivity type well region by means of first conductivity type ion implantation, so that the first conductivity type well region extends downwards to contact the first conductivity type buried layer part B.

In some examples, the step of: in the first conductivity type substrate of the isolation region, performing first conductivity type ion implantation by means of first implantation energy to form a first conductivity type buried layer part A includes:

in the first conductivity type substrate of the isolation region, performing the first conductivity type ion implantation by means of the first implantation energy ranging from 1500 Key to 3000 Key to form the first conductivity type buried layer part A, so that the first conductivity type buried layer part A extends downwards from the upper surface of the first conductivity type substrate.

In some examples, the step of: in the first conductivity type substrate on the first conductivity type buried layer part A, performing first conductivity type ion implantation by means of second implantation energy to form a first conductivity type buried layer part B primary structure, so that the first conductivity type buried layer part B primary structure extends downwards to contact the first conductivity type buried layer part A includes:

in the first conductivity type substrate on the first conductivity type buried layer part A, performing the first conductivity type ion implantation by means of the second implantation energy ranging from 50 Key to 100 Key to form the first conductivity type buried layer part B primary structure, so that the first conductivity type buried layer part B primary structure extends downwards from the upper surface of the first conductivity type substrate, and the first conductivity type buried layer part B primary structure extends downwards to contact the first conductivity type buried layer part A.

In some examples, the method for manufacturing a high-voltage isolation structure further includes, after forming the first conductivity type buried layer part B and before forming the first conductivity type well region:

forming a field oxide layer such that the field oxide layer covers at least the first conductivity type epitaxial layer at the position of the isolation region.

In some examples, the step of: in the first conductivity type epitaxial layer on the first conductivity type buried layer part B, forming a first conductivity type well region by means of first conductivity type ion implantation, so that the first conductivity type well region extends downwards to contact the first conductivity type buried layer part B includes:

in the first conductivity type epitaxial layer on the first conductivity type buried layer part B, forming the first conductivity type well region by means of selective first conductivity type ion implantation, so that the first conductivity type well region extends downwards to contact the first conductivity type buried layer part B and extends upwards to contact the field oxide layer.

In order to solve the technical problem in the described in the background, a second aspect of the present application provides a high-voltage isolation semiconductor device, wherein the high-voltage isolation semiconductor device is manufactured by means of the method for manufacturing a high-voltage isolation semiconductor device according to the first aspect of the present application;

the high-voltage isolation semiconductor device is located in a substrate layer at the position of an isolation region, the isolation region being isolated between a high-voltage device region and a level shift region, the substrate layer including a first conductivity type substrate and a second conductivity type epitaxial layer, the second conductivity type epitaxial layer being formed on the first conductivity type substrate;

the high-voltage isolation semiconductor device includes a first conductivity type buried layer part A, a first conductivity type buried layer part B, and a first conductivity type well region;

the first conductivity type buried layer part B is located at an adjoining surface of the first conductivity type substrate and the second conductivity type epitaxial layer, a lower portion of the first conductivity type buried layer part B extends into the first conductivity type substrate, and an upper portion of the first conductivity type buried layer part B extends into the second conductivity type epitaxial layer;

the first conductivity type buried layer part A is located in the first conductivity type substrate, and the first conductivity type buried layer part A extends upwards to contact the first conductivity type buried layer part B; and

the first conductivity type well region is located in the second conductivity type epitaxial layer, and the first conductivity type well region extends downwards to contact the first conductivity type buried layer part B.

In some examples, the first conductivity type buried layer part A is formed by performing first conductivity type ion implantation by means of first implantation energy ranging from 1500 Key to 3000 Key.

In some examples, the first conductivity type buried layer part B is formed by performing first conductivity type ion implantation by means of second implantation energy ranging from 50 Key to 100 Key.

In some examples, a field oxide layer covers at least the first conductivity type epitaxial layer at the position of the isolation region.

In some examples, the first conductivity type well region extends upwards to contact the field oxide layer.

In some examples, a second conductivity type buried layer is formed in the substrate layer on least one side of the high-voltage isolation semiconductor device, and the second conductivity type buried layer is located at the adjoining surface of the first conductivity type substrate and the second conductivity type epitaxial layer; and

a lower portion of the second conductivity type buried layer extends into the first conductivity type substrate, and an upper portion of the same extends into the second conductivity type epitaxial layer.

The technical solution of the present application has at least the following advantages: in the present application, the first implantation energy for forming the first conductivity type buried layer part A is greater than the second implantation energy for forming the first conductivity type buried layer part B, and the first conductivity type buried layer part A is in direct contact with the first conductivity type substrate, so as to increase the doping concentration of the contact position between the first conductivity type buried layer part A and the first conductivity type substrate. Therefore, even when the concentration of the first conductivity type substrate is very light or the width of the isolation structure is very small, the high-voltage isolation semiconductor device can be prevented from rapidly expanding downwards after lateral depletion, achieving effective isolation between high-voltage circuits and thereby suppressing an electric leakage without affecting the withstand voltage performance of the high-voltage isolation semiconductor device.

### BRIEF DESCRIPTION OF THE DRAWINGS

In order to more clearly explain the specific implementations of the present application or the technical solution in the prior art, the drawings required in description of the specific implementations or the prior art will be briefly described below. It is obvious that the drawings described below are some implementations of the present application, and those skilled in the art could also obtain other drawings on the basis of these drawings, without involving any inventive skill.

FIG. 1 illustrates a flowchart of a method for manufacturing a high-voltage isolation semiconductor device provided by an embodiment of the present application.

FIG. 1a illustrates a schematic diagram of a sectional structure of a device undergoing step S2.

FIG. 1B illustrates a schematic diagram of a sectional structure of a device undergoing step S4.

FIG. 1c illustrates a schematic diagram of a sectional structure of a device undergoing step S5.

FIG. 1d illustrates a schematic diagram of a sectional structure of a device undergoing the formation of a field oxide layer.

FIG. 2 illustrates a sectional schematic diagram of a high-voltage isolation structure manufactured by the method for manufacturing a high-voltage isolation semiconductor device illustrated in FIG. 1.

### DETAILED DESCRIPTION OF THE DISCLOSURE

The technical solution of the present application will be clearly and completely described below with reference to the drawings. Obviously, the described embodiments are part of the embodiments of the present application, rather than all of them. Based on the embodiments in the present application, all other embodiments obtained by those skilled in the art without involving any inventive skill shall fall into the protection scope of the present application.

In the description of the present application, it should be noted that the orientation or position relationship indicated by the terms “center”, “upper”, “lower”, “left”, “right”, “vertical”, “horizontal”, “inner”, “outer”, etc. is based on the orientation or position relationship shown in the drawings, intended only for the convenience of describing the present application and simplifying the description, rather than indicating or implying that the apparatus or element referred to necessarily has a specific orientation or is configured or operated in a specific orientation, and thus cannot be construed as a limitation on the present application. In addition, the terms “first”, “second”, and “third” are used for descriptive purposes only, and cannot be construed as indicating or implying relative importance.

In the description of the present application, it should be noted that, unless otherwise clearly specified and limited, the terms “mounting”, “coupling”, and “connecting” should be understood in a broad sense, for example, it can be a fixed connection, a detachable connection, or an integrated connection, can be a mechanical connection or an electrical connection, can be a direct connection, an indirect connection implemented by means of an intermedium, or an internal connection between two components, and can be a wireless connection or a wired connection. Those skilled in the art could understand the specific meanings of the above terms in the present application on the basis of specific situations.

In addition, the technical features involved in different embodiments of the present application described below can be combined with each other in the case of no conflict.

In the present application, the first conductivity type is opposite to the second conductivity type, wherein the first conductivity type and the second conductivity type each may be N-type or P-type. When the first conductivity type is N-type, the second conductivity type is P-type, and when the first conductivity type is P-type, the second conductivity type is N-type.

Hereinafter, the technical solution of the present application is described by taking the first conductivity type being P-type and the second conductivity type being N-type as an example.

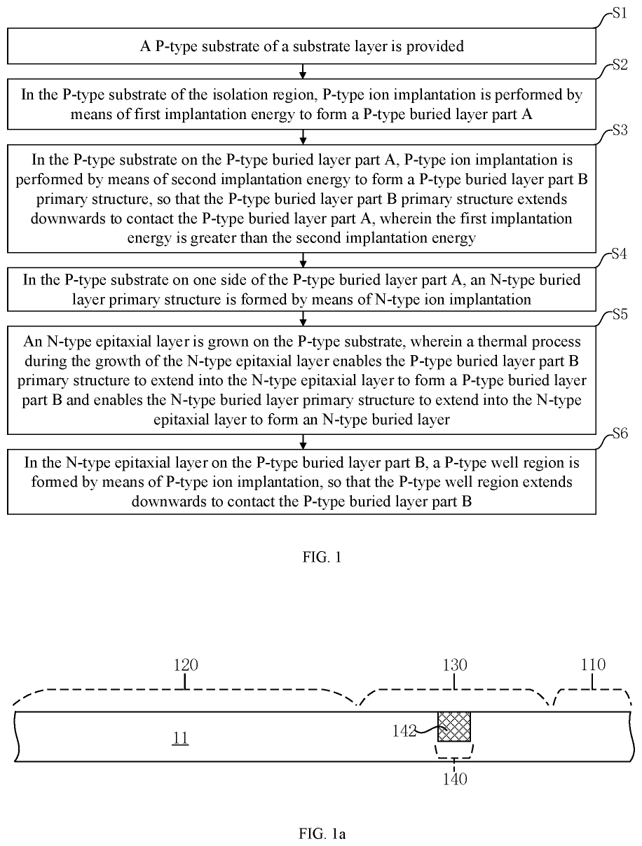

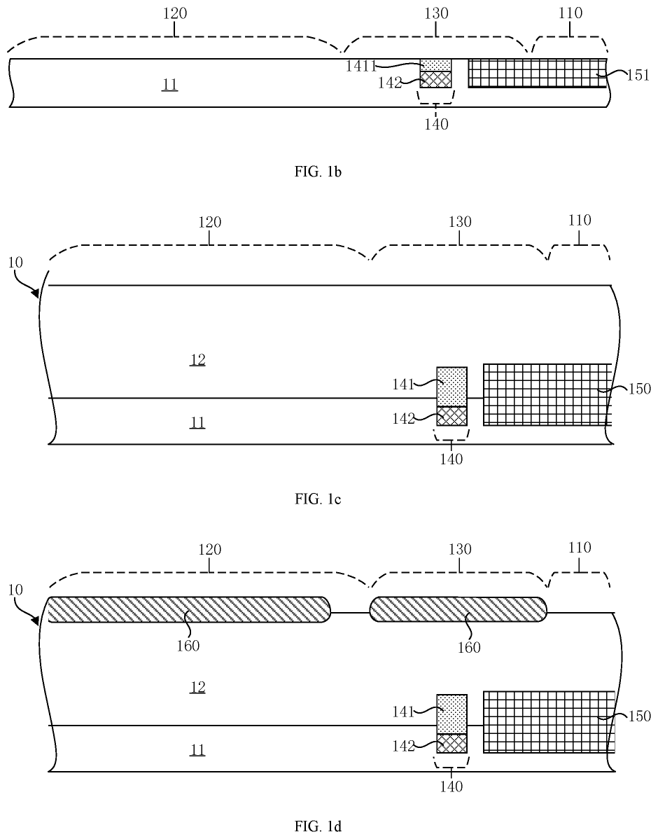

FIG. 1 illustrates a flowchart of a method for manufacturing a high-voltage isolation semiconductor device provided by an embodiment of the present application. As can be seen from FIG. 1, the method for manufacturing a high-voltage isolation semiconductor device includes the following steps S1 to S6 sequentially performed.

Step S1: A P-type substrate of a substrate layer is provided, the substrate layer including at least a high-voltage device region, a level shift region, and an isolation region, the isolation region being isolated between the high-voltage device region and the level shift region.

The high-voltage device region is used to form a high-voltage device, and the level shift region is used to form a level shift, wherein a drain of the formed level shift is close to the high-voltage device. The isolation region is used to form a high-voltage isolation semiconductor device that isolates the high-voltage device from the drain of the level shift.

Step S2: In the P-type substrate of the isolation region, P-type ion implantation is performed by means of first implantation energy to form a P-type buried layer part A.

Referring to FIG. 1a that illustrates a schematic diagram of a sectional structure of a device undergoing step S2, it can be seen from FIG. 1a that the P-type buried layer part A 142 is formed in the P-type substrate 11 at the position of the isolation region 130.

Step S3: In the P-type substrate on the P-type buried layer part A, P-type ion implantation is performed by means of second implantation energy to form a P-type buried layer part B primary structure, so that the P-type buried layer part B primary structure extends downwards to contact the P-type buried layer part A, wherein the first implantation energy is greater than the second implantation energy.

The first implantation energy for forming the P-type buried layer part A is greater than the second implantation energy for forming the P-type buried layer part B, and the P-type buried layer part A is in direct contact with the P-type substrate, so as to increase the doping concentration of the contact position between the P-type buried layer part A and the P-type substrate.

Step S4: In the P-type substrate on one side of the P-type buried layer part A, an N-type buried layer primary structure is formed by means of N-type ion implantation.

Referring to FIG. 1B that illustrates a schematic diagram of a sectional structure of a device undergoing step S4, it can be seen from FIG. 1B that, the P-type buried layer part B primary structure 1411 is formed in the P-type substrate 11 on the P-type buried layer part A 142, the P-type buried layer part B primary structure 1411 extends downwards from the upper surface of the P-type substrate 11, and the P-type buried layer part B primary structure 1411 is in contact with the P-type buried layer part A 142. On one side of the P-type buried layer part A 142 and the P-type buried layer part B primary structure 1411 stacked vertically, the N-type buried layer primary structure 151 is formed, and the N-type buried layer primary structure 151 extends downwards from the upper surface of the P-type substrate 11. The N-type buried layer primary structure 151 in this embodiment bridges the isolation region 130 and the high-voltage device region 110.

Step S5: An N-type epitaxial layer is grown on the P-type substrate, wherein a thermal process during the growth of the N-type epitaxial layer enables the P-type buried layer part B primary structure to extend into the N-type epitaxial layer to form a P-type buried layer part B and enables the N-type buried layer primary structure to extend into the N-type epitaxial layer to form an N-type buried layer.

Referring to FIG. 1c that illustrates a schematic diagram of a sectional structure of a device undergoing step S5, it can be seen from FIG. 1c that the P-type buried layer part B 141 formed after the expansion is located at an adjoining surface of the P-type substrate 11 and the N-type epitaxial layer 12, a lower portion of the P-type buried layer part B 141 extends into the P-type substrate 11, and an upper portion of the same extends into the N-type epitaxial layer 12. Similarly, the N-type buried layer 150 formed after the expansion is also located at the adjoining surface of the P-type substrate 11 and the N-type epitaxial layer 12, a lower portion of the N-type buried layer 150 extends into the P-type substrate 11, and an upper portion of the same extends into the N-type epitaxial layer 12.

Step S6: In the N-type epitaxial layer on the P-type buried layer part B, a P-type well region is formed by means of P-type ion implantation, so that the P-type well region extends downwards to contact the P-type buried layer part B.

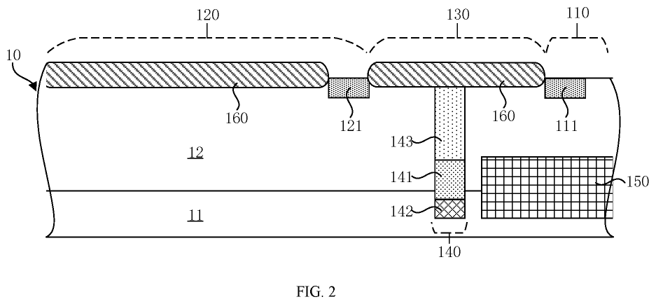

Referring to FIG. 2 that illustrates a schematic diagram of a sectional structure of a device formed by the method for manufacturing a high-voltage isolation semiconductor device provided by the present application, it can be seen from FIG. 2 that the P-type well region 143 extends downwards to contact the P-type buried layer part B 141.

The P-type buried layer part A 142, the P-type buried layer part B 141, and the P-type well region 143 are sequentially stacked from bottom to top to form a P-type high-voltage isolation semiconductor device. The bottom (i.e., the P-type buried layer part A) of the P-type high-voltage isolation semiconductor device is in contact with the P-type substrate, so that the P-type substrate is grounded, forming a path starting from the P-type well region 143, sequentially passing through the P-type buried layer part B 141, the P-type buried layer part A 142, and the P-type substrate 11, and ending at the ground.

In this embodiment, the first implantation energy for forming the first conductivity type buried layer part A is greater than the second implantation energy for forming the first conductivity type buried layer part B, and the first conductivity type buried layer part A is in direct contact with the first conductivity type substrate, so as to increase the doping concentration of the contact position between the first conductivity type buried layer part A and the first conductivity type substrate. Therefore, even when the concentration of the first conductivity type substrate is very light or the width of the isolation semiconductor device is very small, the high-voltage isolation semiconductor device can be prevented from rapidly expanding downwards after lateral depletion, achieving effective isolation between high-voltage circuits and thereby suppressing an electric leakage without affecting the withstand voltage performance of the high-voltage isolation semiconductor device.

Optionally, in step S2, the P-type ion implantation may be performed in the P-type substrate at the position of the isolation region by means of the first implantation energy ranging from 1500 Key to 3000 Key to form the P-type buried layer part A, so that the P-type buried layer part A extends downwards from the upper surface of the P-type substrate to form the device structure illustrated in FIG. 1a.

In step S3, the P-type ion implantation may be performed in the P-type substrate on the P-type buried layer part A by means of the second implantation energy ranging from 50 Key to 100 Key to form the P-type buried layer part B primary structure, so that the P-type buried layer part B primary structure extends downwards from the upper surface of the P-type substrate, and the P-type buried layer part B primary structure extends downwards to contact the P-type buried layer part A to form the device structure illustrated in FIG. 1b.

The method for manufacturing a high-voltage isolation semiconductor device provided by this embodiment of the present application may further include the following step performed after step S5 and before step S6: forming a field oxide layer such that the field oxide layer covers at least the P-type epitaxial layer at the position of the isolation region, so as to form the device structure illustrated in FIG. 1d. As can be seen from FIG. 1d, the formed field oxide layer 160 covers at least the P-type epitaxial layer 12 at the position of the isolation region 130.

After the field oxide layer is formed, in step S6, a P-type well region implantation region can be defined by means of a photolithography process, and then the P-type well region is formed in the P-type well region implantation region by means of P-type ion implantation. The position of the P-type well region implantation region is consistent with the position of the P-type buried layer part B formed after step S5.

After step S6, the drain 121 of the level shift may be formed in the level shift region 120 by means of source-drain ion implantation in the related art, and a source or drain 111 of the high-voltage device may be formed in the high-voltage device region 110, so as to form the device structure illustrated in FIG. 2.

Referring to FIG. 2 that illustrates a sectional schematic diagram of a high-voltage isolation semiconductor device manufactured by the method for manufacturing a high-voltage isolation semiconductor device illustrated in FIG. 1, it can be seen from FIG. 2 that, a substrate layer 10 includes a high-voltage device region 110 and a level shift region 120, an isolation region 130 is formed at least in the substrate layer 10 between the high-voltage device region 110 and the level shift region 120, and a high-voltage isolation semiconductor device 140 is formed in the isolation region 130. A high-voltage device having a relatively high working voltage VB is formed in the high-voltage device region 110, and a level shift is formed in the level shift region 120. A drain 121 of the level shift is close to the high-voltage device, and a drain voltage VD of the level shift and the working voltage VB of the high-voltage device are both high voltages.

The substrate layer 10 includes a P-type substrate 11 and an N-type epitaxial layer 12 formed on the P-type substrate 11.

The high-voltage isolation semiconductor device 140 includes a P-type buried layer part B 141, a P-type buried layer part A 142, and a P-type well region 143.

The P-type buried layer part B 141 is located at an adjoining surface of the P-type substrate 11 and the N-type epitaxial layer 12, a lower portion of the P-type buried layer part B 141 extends into the P-type substrate 11, and an upper portion of the P-type buried layer part B 141 extends into the N-type epitaxial layer 12.

The P-type buried layer part A 142 is located in the P-type substrate 11, and the P-type buried layer part A 142 extends upwards to contact the lower surface of the P-type buried layer part B 141.

The P-type well region 143 is located in the N-type epitaxial layer 12, and the P-type well region 143 extends upwards to the upper surface of the N-type epitaxial layer 12 and extends downwards to contact the upper surface of the P-type buried layer part B 141.

The P-type substrate 11 is grounded, forming a path starting from the P-type well region 143, sequentially passing through the P-type buried layer part B 141, the P-type buried layer part A 142, and the P-type substrate 11, and ending at the ground.

The P-type buried layer part A 142 is formed by performing P-type ion implantation by means of first implantation energy ranging from 1500 Key to 3000 Key. The P-type buried layer part B 141 is formed by performing P-type ion implantation by means of second implantation energy ranging from 50 Key to 100 Key.

A field oxide layer 160 covers at least the P-type epitaxial layer 12 at the position of the isolation region 130, and the P-type well region 143 extends upwards to contact the field oxide layer 160.

An N-type buried layer 150 is formed in the substrate layer 10 on at least one side of the high-voltage isolation semiconductor device 140, and the N-type buried layer 150 is located at the adjoining surface of the P-type substrate 11 and the N-type epitaxial layer 12. A lower portion of the N-type buried layer 150 extends into the P-type substrate 11, and an upper portion of the same extends into the N-type epitaxial layer 12.

In this embodiment, the first implantation energy for forming the first conductivity type buried layer part A is greater than the second implantation energy for forming the first conductivity type buried layer part B, and the first conductivity type buried layer part A is in direct contact with the first conductivity type substrate, so as to increase the doping concentration of the contact position between the first conductivity type buried layer part A and the first conductivity type substrate. Therefore, even when the concentration of the first conductivity type substrate is very light or the width of the isolation structure is very small, the high-voltage isolation semiconductor device can be prevented from rapidly expanding downwards after lateral depletion, achieving effective isolation between high-voltage circuits and thereby suppressing an electric leakage without affecting the withstand voltage performance of the high-voltage isolation semiconductor device.

Obviously, the above embodiments are merely examples used for clear description, rather than for limitation on the implementations. Those skilled in the art could also make other changes or modifications in different forms on the basis of the above description. There is no need or way to exhaustively list all of the implementations herein, but obvious changes or modifications derived herefrom still fall within the protection scope created by the present application.

What is claimed is:

1. A method for manufacturing a high-voltage isolation semiconductor device, wherein the method for manufacturing a high-voltage isolation semiconductor device comprises the following steps:
providing a first conductivity type substrate of a substrate layer, the substrate layer comprising at least a high-voltage device region, a level shift region, and an isolation region, the isolation region being isolated between the high-voltage device region and the level shift region;
in the first conductivity type substrate of the isolation region, performing first conductivity type ion implantation by means of first implantation energy to form a first conductivity type buried layer part A;
in the first conductivity type substrate on the first conductivity type buried layer part A, performing first conductivity type ion implantation by means of second implantation energy to form a first conductivity type buried layer part B primary structure, so that the first conductivity type buried layer part B primary structure extends downwards to contact the first conductivity type buried layer part A, wherein the first implantation energy is greater than the second implantation energy;
in the first conductivity type substrate on one side of the first conductivity type buried layer part A, forming a second conductivity type buried layer primary structure by means of second conductivity type ion implantation;
growing a second conductivity type epitaxial layer on the first conductivity type substrate, wherein a thermal process during the growth of the second conductivity type epitaxial layer enables the first conductivity type buried layer part B primary structure to extend into the second conductivity type epitaxial layer to form a first conductivity type buried layer part B and enables the second conductivity type buried layer primary structure to extend into the second conductivity type epitaxial layer to form a second conductivity type buried layer; and
in the second conductivity type epitaxial layer on the first conductivity type buried layer part B, forming a first conductivity type well region by means of first conductivity type ion implantation, so that the first conductivity type well region extends downwards to contact the first conductivity type buried layer part B.

2. The method for manufacturing a high-voltage isolation semiconductor device according to claim 1, wherein the step of: in the first conductivity type substrate of the isolation region, performing first conductivity type ion implantation by means of first implantation energy to form a first conductivity type buried layer part A comprises:
in the first conductivity type substrate of the isolation region, performing the first conductivity type ion implantation by means of the first implantation energy ranging from 1500 Key to 3000 Key to form the first conductivity type buried layer part A, so that the first conductivity type buried layer part A extends downwards from the upper surface of the first conductivity type substrate.

3. The method for manufacturing a high-voltage isolation semiconductor device according to claim 1, wherein the step of: in the first conductivity type substrate on the first conductivity type buried layer part A, performing first conductivity type ion implantation by means of second implantation energy to form a first conductivity type buried layer part B primary structure, so that the first conductivity type buried layer part B primary structure extends downwards to contact the first conductivity type buried layer part A comprises:
in the first conductivity type substrate on the first conductivity type buried layer part A, performing the first conductivity type ion implantation by means of the second implantation energy ranging from 50 Key to 100 Key to form the first conductivity type buried layer part B primary structure, so that the first conductivity type buried layer part B primary structure extends downwards from the upper surface of the first conductivity type substrate, and the first conductivity type buried layer part B primary structure extends downwards to contact the first conductivity type buried layer part A.

4. The method for manufacturing a high-voltage isolation semiconductor device according to claim 1, wherein the method for manufacturing a high-voltage isolation semiconductor device further comprises, after forming the first conductivity type buried layer part B and before forming the first conductivity type well region forming a field oxide layer such that the field oxide layer covers at least the first conductivity type epitaxial layer at the position of the isolation region.

5. The method for manufacturing a high-voltage isolation semiconductor device according to claim 4, wherein the step of: in the first conductivity type epitaxial layer on the first conductivity type buried layer part B, forming a first conductivity type well region by means of first conductivity type ion implantation, so that the first conductivity type well region extends downwards to contact the first conductivity type buried layer part B comprises:
in the first conductivity type epitaxial layer on the first conductivity type buried layer part B, forming the first conductivity type well region by means of selective first conductivity type ion implantation, so that the first conductivity type well region extends downwards to contact the first conductivity type buried layer part B and extends upwards to contact the field oxide layer.

6. A high-voltage isolation semiconductor device, wherein the high-voltage isolation semiconductor device is manufactured by means of the method for manufacturing a high-voltage isolation semiconductor device according to claim 1;
the high-voltage isolation semiconductor device is located in a substrate layer at the position of an isolation region, the isolation region being isolated between a high-voltage device region and a level shift region, the substrate layer comprising a first conductivity type substrate and a second conductivity type epitaxial layer, the second conductivity type epitaxial layer being formed on the first conductivity type substrate;
the high-voltage isolation semiconductor device comprises a first conductivity type buried layer part A, a first conductivity type buried layer part B, and a first conductivity type well region;
the first conductivity type buried layer part B is located at an adjoining surface of the first conductivity type substrate and the second conductivity type epitaxial layer, a lower portion of the first conductivity type buried layer part B extends into the first conductivity type substrate, and an upper portion of the first conductivity type buried layer part B extends into the second conductivity type epitaxial layer;
the first conductivity type buried layer part A is located in the first conductivity type substrate, and the first conductivity type buried layer part A extends upwards to contact the first conductivity type buried layer part B; and
the first conductivity type well region is located in the second conductivity type epitaxial layer, and the first conductivity type well region extends downwards to contact the first conductivity type buried layer part B.

7. The high-voltage isolation semiconductor device according to claim 6, wherein the first conductivity type buried layer part A is formed by performing first conductivity type ion implantation by means of first implantation energy ranging from 1500 Key to 3000 Key.

8. The high-voltage isolation semiconductor device according to claim 6, wherein the first conductivity type buried layer part B is formed by performing first conductivity type ion implantation by means of second implantation energy ranging from 50 Key to 100 Key.

9. The high-voltage isolation semiconductor device according to claim 6, wherein a field oxide layer covers at least the first conductivity type epitaxial layer at the position of the isolation region.

10. The high-voltage isolation semiconductor device according to claim 9, wherein the first conductivity type well region extends upwards to contact the field oxide layer.

11. The high-voltage isolation semiconductor device according to claim 6, wherein a second conductivity type buried layer is formed in the substrate layer on least one side of the high-voltage isolation semiconductor device, and the second conductivity type buried layer is located at the adjoining surface of the first conductivity type substrate and the second conductivity type epitaxial layer; and a lower portion of the second conductivity type buried layer extends into the first conductivity type substrate, and an upper portion of the same extends into the second conductivity type epitaxial layer.
